(19) United States
(12) Patent Application Publication
(10) Pub. No.: US 2011/0100438 A1
(43) Pub. Date: May 5, 2011

(54) BUILDING INTEGRATED PHOTOVOLTAIC HAVING INJECTION MOLDED COMPONENT

(76) Inventors: Ryan S. Gaston, Midland, MI (US); James R. Keenihan, Midland, MI (US); Jason A. Reese, Auburn, MI (US); James C. Stevens, Richmond, TX (US); Scott T. Matteucci, Midland, MI (US); Lamy J. Chopin, III, Missouri City, TX (US); Gary R. Marchand, Lake Jackson, TX (US); Kim L. Walton, Lake Jackson, TX (US)

(21) Appl. No.: 12/939,412

(22) Filed: Nov. 4, 2010

Related U.S. Application Data
(60) Provisional application No. 61/257,999, filed on Nov. 4, 2009.

(51) Int. Cl. H01L 31/02; C08L 23/12

(52) U.S. Cl. 136/252; 524/528

(57) ABSTRACT

The invention is a photovoltaic device comprising a photovoltaic cell assembly with an injection molded portion connected to at least one edge of the photovoltaic cell assembly where the body portion has properties and a composition enabling robust function over a period of years when the photovoltaic device is mounted on the exterior of a building.

### CROSS-REFERENCE TO RELATED APPLICATION(S)

This application claims benefit of priority from U.S. Provisional Patent Application No. 61/257,999, filed Nov. 4, 2009, which application is incorporated by reference herein in its entirety.

This invention was made with U.S. Government support under contract DE-FC36-07G01754 awarded by the Department of Energy. The U.S. Government has certain rights in this invention.

### FIELD OF THE INVENTION

This invention relates to photovoltaic articles that are installed as integral to a building structure and that include an injection molded component.

### BACKGROUND OF THE INVENTION

Solar energy, especially photovoltaic (PV) energy wherein sunlight is converted directly into electrical energy, has many desirable features. However, the cost of manufacturing and installing solar energy products, especially PV products, has limited the widespread penetration of these products into the marketplace. Development of solar energy systems that can also function as part of a building structure (sometimes referred to as Building-Integrated Photovoltaics, or BIPV) is desired to improve energy efficiency in a cost effective manner. Such systems need to have sufficient durability under the variety of environmental conditions to which they would be subjected on the exterior of a structure while also meeting building code requirements and being cost effective to manufacture, in addition to the ability to efficiently convert sunlight into electricity.

Injection molding of polymers is known as a method to conveniently form polymers in desired shapes.

### SUMMARY OF THE INVENTION

Applicants have discovered that in order to form a BIPV article using injection molding, the composition being injection molded must meet very specific requirements in order to attain the desired requirements of durability, flame resistance and manufacturability in the final article. More specifically, while molding large complex parts is generally feasible with low molecular weight materials, applicants have discovered these materials generally will not have sufficiently robust properties to withstand outdoor exposures for long periods. Thus, prior to this invention there was still a need in the art for cost effective polymeric formulations that combine good processability and the ability to be used on injection molding equipment to fill large, complex molds as well as the ability to withstand outdoor exposures for long periods. In addition, it would be desirable for such polymeric formulations to resist ignition or possess a degree of flame resistance.

Thus, according to a first embodiment the invention is a photovoltaic article comprising a photovoltaic cell assembly and a body portion connected to at least one edge of the photovoltaic cell assembly wherein the body portion comprises a composition having the following characteristics:
a) a melt flow rate of at least 5 g/10 minutes and no greater than 100 g/10 minutes;
b) a coefficient of linear thermal expansion (CLTE) which is within factor of 20, more preferably within a factor of 15, still more preferably within a factor of 10, even more preferably within a factor of 5, and most preferably within a factor of 2 of the CLTE of the photovoltaic cell assembly; and
c) an RTI Electrical and an RTI Mechanical Strength rating, each of which is at least 85° C., preferably at least 90° C., more preferably at least 95° C., still more preferably at least 100° C., and most preferably at least 105° C.

According to one preferred embodiment of the first embodiment, the photovoltaic cell assembly includes a glass layer and the composition of the body portion has a flexural modulus of up to 7000 MPa and a tensile elongation at break of at least 3% of original length. In this preferred embodiment the composition preferably comprises polypropylene and from 5 to 50% by weight of a reinforcement component (preferably glass fibers).

According to a second embodiment, the invention is a photovoltaic article comprising a photovoltaic cell assembly and a body portion connected to at least one edge of the photovoltaic cell assembly wherein the body portion comprises a composition having the following characteristics:
a) a melt flow rate of at least 5 g/10 minutes and no greater than 100 g/10 minutes;
b) a flexural modulus of at least 500 MPa and no greater than 1500 MPa
c) a tensile elongation at break of at least 100% of original length; and
d) an RTI Electrical and an RTI Mechanical Strength rating, each of which is at least 85° C., preferably at least 90° C., more preferably at least 95° C., still more preferably at least 100° C., and most preferably at least 105° C. Preferably, this embodiment has the CLTE characteristics as recited in the first embodiment above. Preferably this embodiment includes a flexible photovoltaic cell assembly.

In each of the above embodiments, the composition preferably is further characterized by an RTI Flammability rating, which is at least 85° C., preferably at least 90° C., more preferably at least 95° C., still more preferably at least 100° C., and most preferably at least 105° C. Most preferably, the body composition is further characterized by an RTI a Mechanical Impact rating, each of which is at least 85° C., preferably at least 90° C., more preferably at least 95° C., still more preferably at least 100° C., and most preferably at least 105° C. Finally, the photovoltaic article preferably has sufficient flammability resistance such that a roofing construction containing the photovoltaic article passes the UL 790 tests with at least a Class B rating, more preferably a Class A rating.

According to a third embodiment the invention is a photovoltaic article comprising a photovoltaic cell assembly and a body portion comprising an injection molded composition connected to at least one edge of the photovoltaic cell assembly wherein the injection molded composition comprises:

(a) from 20 to 80% by weight of a polymeric material which is polypropylene or a copolymer of propylene and ethylene or mixtures thereof which has a melt flow rate of between 5 and 100 g/10 minutes;
(b) from 5 to 30% by weight of a polyethylene or ethylene/α-olefin copolymer which has a melt index of between 1 and 100 g/10 minutes and a density of at least 0.85 g/cm³ more preferably at least 0.86, and most preferably at least 0.865 and preferably less than 0.97, more preferably less than 0.92 and most preferably less than 0.89; and
(c) up to 50%, preferably from 10 to 50% by weight of an fire retardant material, preferably an inorganic fire retardant material.

According to a fourth embodiment, the invention is the injection molded composition as recited in the third embodiment.

### BRIEF DESCRIPTION OF THE DRAWINGS

FIG. 1 shows an illustrative example of a photovoltaic article according to one embodiment of the present invention as it would appear installed on a structure adjacent to additional like photovoltaic articles.

FIG. 2 shows the dimensional change over a temperature range for a representative composition useful in the present invention.

### DETAILED DESCRIPTION OF THE INVENTION

The photovoltaic article can be described generally as a three dimensional article that includes an energy producing device (e.g. solar cells), electrical circuitry to transfer the energy produced, and a body which holds the energy producing device and allows it to be effectively mounted onto a structure. The body or a portion of it is formed from the material having the properties and/or composition as described herein and is preferably injection molded around the energy producing device and optionally the electrical circuitry.

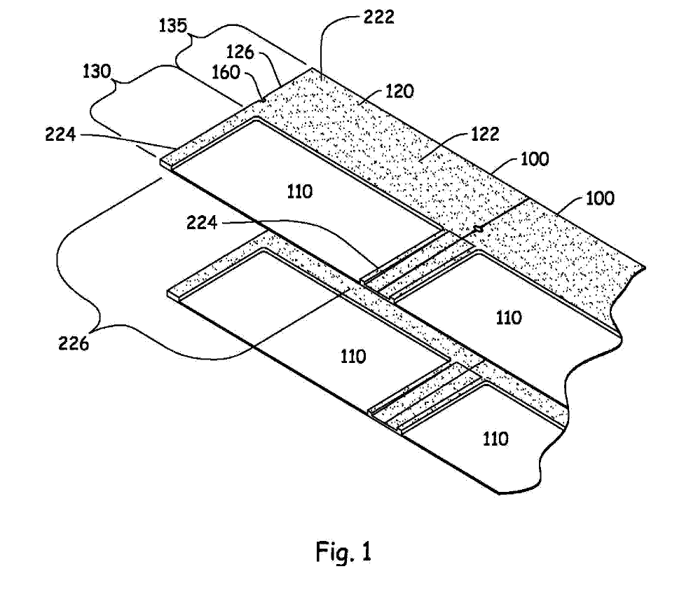

For example, as shown in FIG. 1, the PV device 100, which is suitable for use as a shingle or other building fascia, can be further described as including a photovoltaic cell assembly 110 and a body portion 120 (which can also be referred to as a body support portion where it provides structural support). The body portion 120 has an upper surface portion 122, a lower surface portion 124 (not shown) and side wall portion 126 spanning therebetween. The body portion 120 can be further described as including a main body portion 222 located adjacent on one side to the photovoltaic cell assembly 110, and a side body portion 224 extending from the main body portion 222 does at least one other side of the photovoltaic cell assembly 110. An optional bottom body portion could be located at 226 on the opposite side of the photovoltaic cell assembly 110 from the main body portion 222 thereby having the body form a full frame around the photovoltaic cell assembly 110. The body portion may also include optional locator 160 to locate PV device (e.g. shingle) properly relative to the adjacent PV device. In an alternative description, the PV device 100 can also be described as having an active portion 130 and an inactive portion 135. The active portion 130 can include at least the photovoltaic cell assembly 110, a portion of the side body portion 224 and the optional bottom body portion 226. The inactive portion 135 can include at least the main body portion 222, a portion of the side body portion 224, and some or all of the electrical circuitry of the PV device 100. This exemplary photovoltaic article would normally be installed in electrical connection to adjacent photovoltaic articles which would be electrically connected to the electrical system within the structure or grid so as to effectively use the electricity produced by the article.

As further example, the photovoltaic cell assembly 110 can be further described as including a photovoltaic cell, protective layers, optional adhesive layers, and at least some of the electrical circuitry of the PV device. In one preferred embodiment the photovoltaic cell assembly comprises a glass barrier layer. The PV article 100 can also be described in an alternative fashion. The PV devices 100 can include components such as the photovoltaic cell assembly 110, at least one buss terminal, and a body portion 120. The PV devices 100 can include at least one peripheral edge, at least one photovoltaic cell inboard of the at least one peripheral edge. The at least one buss terminal, which can function to transfer current to or from the photovoltaic cell assembly 110 via at least one integral photovoltaic connector assembly located within or at the at least one peripheral edge.

The lower surface portion 124 can contact the structure (e.g. building substrate and/or structure). The upper surface portion 122 can receive a fastener (not shown, e.g. nail, screw, staple, rivet, etc.) that attaches the photovoltaic device 100 to the structure. Furthermore, the body portion 120 can be at least partially joined to at least one edge portion of the photovoltaic cell assembly 110 along at least a portion of a bottom segment of the body portion 120 while leaving at least a portion of the at least one photovoltaic cell exposed to receive radiation.

It is contemplated that the PV article 100 can be constructed at least partially of flexible materials to allow at least some flexibility for conforming to an irregular contour in a building structure. It is also contemplated that it can be desirable to at least keep the photovoltaic cell relatively rigid, generally to prevent any cracking of the cell. Thus, some parts of the PV device can be constructed with a more rigid material (e.g. glass plate, mineral filled composites, or polymeric sheets). Although, the photovoltaic cell can be partially or substantially rigid, it is possible for the PV device to be generally flexible. For this invention, flexible means that the PV device is more flexible or less rigid than the substrate (e.g. structure) to which it is attached. Preferably, in the case of a flexible substrate, the PV device can bend about a 1 meter diameter cylinder without a decrease in performance. Preferably, in the case of a rigid substrate the PV device can bend about a 20 meter diameter cylinder without a decrease in performance. For example, in the case of a PV device shingle, shingles generally are less rigid than the roof deck; the roof deck provides structural rigidity. In some other examples the roofing product itself provides the necessary rigidity and the roof deck is absent, or minimized.

For a BIPV device which functions as a roofing shingle or other building fascia, the inventors have discovered that a preferred overmolding composition should meet a number of property requirements. The preferred composition should possess a balance of properties, many of which present conflicting demands on the material properties. For example, a BIPV roofing shingle should be tough and strong, and retain tensile properties over a long life exposed to the sunlight and weather. These properties are best achieved using a high molecular weight polymer composition. However, the injection molding process generally requires polymers of relatively lower molecular weight, so that the molding pressures, clamping forces, and energy required are not too high. In addition, when high molecular weight (low MFR) compounds are used in an overmolding process, especially one involving the use of a fragile PV cell and/or a glass member, the forces generated by using a viscous overmolding composition may place stresses on these sensitive components, causing breakage and low yields of finished BIPV products. Finally, compatibility of the overmold composition with the photovoltaic cell assembly over a range of environmental conditions is important. Thus, the preferred overmolding composition is a narrow selection of molecular weight and flow properties, balancing durability with processability, for example.

In addition, the modulus of the composition is important for injection overmolding of BIPV products, especially for shingle applications. An extremely rigid composition will be better for resisting wind-uplifting and failure during storms, but a low-modulus elastomer is better for placing less stress on a PV cell as a result of the composition shrinking as it cools from the melt. In addition, a low modulus material may conform to irregularities in the roof better than a more rigid shingle.

In addition, a BIPV roofing product, especially a shingle product, should be resistant to fire ignition. Generally, the addition of fire-retardant (FR) compounds, especially inorganic FR compounds, increases the modulus and decreases the processability of a polymeric composition. There is a balance of Mw, FR type and % of the composition, modulus, toughness, crack resistance, impact resistance, and processability for a BIPV overmolding composition that must be met to achieve the desired weatherability, electrical performance, fire resistance, and functionality in a BIPV application.

The photovoltaic cell contemplated in the present invention may be constructed of any number of known photovoltaic cells commercially available or may be selected from some future developed photovoltaic cells. These cells function to translate light energy into electricity. The photoactive portion of the photovoltaic cell is the material which converts light energy to electrical energy. Any material known to provide that function may be used including crystalline silicon, gallium arsenides, cadmium tellurides, or amorphous silicons. However, the photoactive layer is preferably a layer of IB-IIIA-chalcogenide, such as IB-IIIA-selenides, IB-IIIA-sulfides, or IB-IIIA-selenide sulfides. More specific examples include copper indium selenides, copper indium gallium selenides, copper gallium selenides, copper indium sulfides, copper indium gallium sulfides, copper gallium selenides, copper indium sulfide selenides, copper gallium sulfide selenides, and copper indium gallium sulfide selenides (all of which are referred to herein as CIGSS). These can also be represented by the formula CuIn(1−x)GaxSe(2−y)Sy where x is 0 to 1 and y is 0 to 2. The copper indium selenides and copper indium gallium selenides are preferred. Additional electroactive layers such as one or more of emitter (buffer) layers, conductive layers (e.g. transparent conductive layers) and the like as is known in the art to be useful in CIGSS based cells are also contemplated herein. These cells may be flexible or rigid and come in a variety of shapes and sizes, but generally are fragile and subject to environmental degradation. In a preferred embodiment, the photovoltaic cell assembly 110 is a cell that can bend without substantial cracking and/or without significant loss of functionality. Exemplary photovoltaic cells are taught and described in a number of US patents and publications, including U.S. Pat. No. 3,767,471, U.S. Pat. No. 4,465,575, US20050011550 A1, EP841706 A2, US20070256734 al, EP1032051A2, JP2216874, JP2143468, and JP10189924a, incorporated hereto by reference for all purposes.

As used herein with respect to a chemical compound, unless specifically indicated otherwise, the singular includes all isomeric forms and vice versa (for example, “hexane”, includes all isomers of hexane individually or collectively). The terms “compound” and “complex” are used interchangeably herein to refer to organic-, inorganic- and organometal compounds. Similarly, unless stated explicitly to the contrary, when reference is to a homopolymer it includes mixtures of various versions of that homopolymer (e.g. various molecular weights, various degrees of linearity or branching, etc.) and reference to copolymer includes mixtures of various versions of such copolymers (e.g. various molecular weights, various degrees of linearity or branching, various relative amounts of each comonomer, etc.)

The composition used in the body portion has a melt flow rate of at least 5 g/10 minutes, more preferably at least 10 g/10 minutes. The melt flow rate is preferably less than 100 g/10 minutes, more preferably less than 50 g/10 minutes and most preferably less than 30 g/10 minutes. The melt flow rate of compositions were determined by test method ASTM D1238-04, “REV C Standard Test Method for Melt Flow Rates of Thermoplastics by Extrusion Plastometer”, 2004 Condition L (230° C./2.16 Kg). Polypropylene resins used in this application also use this same test method and condition. The melt flow rate of polyethylene and ethylene—α-olefin copolymers in this invention are measured using Condition E (190° C./2.16 Kg), commonly referred to as the melt index.

In all embodiments, the compositions have flexural modulus of at least 500 MPa, more preferably at least 600 MPa and most preferably at least 700 MPa. According to the preferred embodiment where the photovoltaic cell assembly includes a glass layer, the flexural modulus is preferably at least 1000 and no greater than 7000 MPa. According to the second embodiment, the flexural modulus is no greater than 1500 MPa, more preferably no greater than 1200 MPa, most preferably no greater than 1000 MPa. The flexural modulus of compositions were determined by test method ASTM D790-07 (2007) using a test speed of 2 mm/min.

When glass is used in the photovoltaic cell assembly, the compositions have an elongation at break of at least 3% but not typically more than 50%. In the second embodiment the body composition material preferably has an elongation at break of at least 100%, more preferably at least 200%, more preferably still at least 300% and preferably no more than 500%. The tensile elongation at break of compositions were determined by test method ASTM D638-08 (2008) using a test speed of 50 mm/min.

The compositions useful herein are characterized as having both an RTI Electrical and an RTI Mechanical Strength rating, each of which is at least 85° C., preferably at least 90° C., more preferably at least 95° C., still more preferably at least 100° C., and most preferably at least 105° C. Preferably, the novel compositions are characterized as having an RTI Electrical, an RTI Mechanical Strength, and an RTI Flammability rating, each of which is at least 85° C., preferably at least 90° C., more preferably at least 95° C., still more preferably at least 100° C., and most preferably at least 105° C. Most preferably, these compositions are characterized as having an RTI Electrical, an RTI Mechanical Strength, an RTI Flammability, and an RTI Mechanical Impact rating, each of which is at least 85° C., preferably at least 90° C., more preferably at least 95° C., still more preferably at least 100° C., and most preferably at least 105° C.

RTI (Relative Thermal Index) is determined by the test procedure detailed in UL 746B (Nov. 29, 2000). Essentially a key characteristic of the plastic is measured at the start of the test (for instance tensile strength), and then samples placed in at least four elevated temperatures (e.g. 130, 140, 150, 160 deg C.) and samples periodically tested throughout several months; The reductions in key properties are then tested, and working criteria established from comparison results of known materials of proven field service; The effective lifetime of the unknown sample is then determined compared to the known material. RTI is expressed in degrees C. The test takes a minimum of 5000 hours to complete, and can be both time-consuming and costly.

Because RTI is an expensive and time-consuming test, a useful proxy for guiding the skilled artisan in selecting useful compositions is the melting point, as determined by differential scanning calorimetry (DSC). It is preferred that for the compositions set forth as useful herein, no melting point is seen at temperatures less than 160° C. in differential scanning calorimetry for a significant portion of the composition and preferably no melting point is seen under 160° C. for the entire composition. The Differential Scanning calorimetry profiles were determined by test method ASTM D7426-08 (2008) with a heating rate of 10° C./min If a significant fraction of the injection molding composition melts at temperatures below 160° C., it is unlikely that the composition will pass the UL RTI tests 746B for Electrical, Mechanical Strength, Flammability, and Mechanical Impact with a high enough rating to adequately function in a building-integrated PV device.

The article preferably is characterized in that when assembled on a standard residential roofing structure in a system of similar articles the structure passes the UL 790 (Apr. 22, 2004) flammability test at least at a class B rating and more preferably at a class A rating. UL-790 is comprised of three tests. One is the spreading flame test, where the deck is arranged at a predetermined angle to a propane torch.

UL 790—Spreading Flame Test: Flame from the torch is blown up the deck surface at 12 mph for 10 minutes. UL-790 requires that the flame does not burn beyond 6′ for Class A, and 8′ for Class B from the point of ignition and the flame fails to spread to both edges of the roof deck.

UL 790—Burning Brand Test: The second test, called a burning brand test, involves placing a burning deck of wood as specified by UL-790 on the sample roof deck. The burning brand of wood is 12″×12″ for Class A and 6″×6″ for Class B testing. The brand is placed at the point of weakest anticipated fire resistance and is allowed to burn itself out. UL-790 requires that the roof decking not be exposed to flames, airborne brands are not produced, no portion of the roof deck may fall away in the form of glowing particles, and no flaming at any time on the underside of the roof deck.

UL 790—Intermittent Flame Test: The final test is referred to as the intermittent flame test. The test sample is arranged in the relation to a propane torch in the same manner discussed for the spreading flame test. The flame is intermittently applied for 2 minutes and then the flame remains off for two minutes. This cycle is repeated 15 times for Class A and 8 times for Class B. After the last flame application the air current is to be maintained until all evidence of flame, glow, and smoke have disappeared from the exposed sample surface. As with the burning brand test, the UL-790 test requires that the roof decking not be exposed to flames, airborne brands are not produced, no portion of the roof deck may fall away in the form of glowing particles, and no flaming at any time on the underside of the roof deck.

Preferably, the compositions disclosed herein are also characterized by a coefficient of linear thermal expansion (CLTE) is within factor of 20, more preferably within a factor of 15, still more preferably within a factor of 10, even more preferably within a factor of 5, and most preferably within a factor of 2 of the CLTE of the photovoltaic cell assembly. For example, if the photovoltaic cell assembly has a CLTE of 9 microns/meter-° C., then the CLTE of the molding composition is preferably between 180 microns/meter-° C. and 0.45 microns/meter-° C. (a factor of 20); more preferably between 135 microns/meter-° C. and 0.6 microns/meter-° C. (a factor of 15); still more preferably between 90 microns/meter-° C. and 0.9 microns/meter-° C. (a factor of 10); even more preferably between 45 microns/meter-° C. and 1.8 microns/meter-° C. (a factor of 5) and most preferably between 18 microns/meter-° C. and 4.5 microns/meter-° C. (a factor of 2). Matching the CLTE's between the composition and the photovoltaic cell assembly is important for minimizing thermally-induced stresses on the BIPV device during temperature changes, which can potentially result in cracking, breaking of PV cells, etc.

CLTE for the compositions disclosed herein is determined on a TA Instruments TMA Model 2940 by test method ASTM E1824-08 (2008) in a temperature range of −40° C. and 90° C., at 5° C. per minute, using the standard software provided with the instrument. The skilled artisan will appreciate that a composition may exhibit temperature ranges where the CLTE changes from other regions as the material undergoes thermal transitions. In such a case, the preferred ranges for CLTE above refer to the largest measured CLTE for the compositions and/or photovoltaic cell assembly. A photovoltaic device may include many different materials, including materials with very different CLTE. For example, a photovoltaic cell assembly may include solar cells, metal conductors, polymeric encapsulants, barrier materials such as glass, or other disparate materials, all with different CLTE's. The CLTE of the photovoltaic cell assembly may be determined by measuring the dimensions of the assembly at a number of temperatures between −40° C. and 90° C.

For some embodiments of the photovoltaic articles disclosed herein, the photovoltaic cell assembly includes a glass barrier layer. If the photovoltaic cell assembly includes a glass layer, the CLTE of the molding composition is preferably less than 80 microns/meter-° C., more preferably less than 70 microns/meter-° C., still more preferably less than 50 microns/meter-° C., and most preferably less than 30 microns/meter-° C. Preferably, the CLTE of the novel composition is greater than 5 microns/meter-° C.

After mold shrinkage can be measured on samples that were stored at 23° C. for approximately 40 hrs after molding using methods described in ASTM D955-08 (2008). Both the gross flow and flow shrinkage can be measured. Preferably, the materials used show less than 2% shrinkage, more preferably less than 1% shrinkage.

The IZOD Impact test of compositions was determined by test method ASTM D256-06 (2006) at temperature of 23° C. The compositions of this should not fully break in testing, more preferably show no break in testing.

According to the third and fourth embodiments of this invention, the composition useful in this invention comprises components A, B, and, preferably component C. Component A is a polypropylene or a copolymer of propylene and ethylene or combinations thereof which has a melt flow rate (MFR) of at least 5 g/10 minutes. Preferably the MFR is at least 10 g/10 minutes and preferably is no greater than 100 g/minutes, more preferably no greater than 50 g/10 minutes. If polypropylene homopolymer is used it is preferred that it have xylene solubles of less than 6%, more preferably less than 5% (ASTM-D5492-06). If a copolymer of propylene and ethylene is used up to about 20% ethylene, more preferably up to about 15% ethylene. The amount of this component A is preferably at least 20% by weight, more preferably at least 30% by weight and preferably less than 80% by weight, more preferably less than 60% by weight and most preferably less than 50% by weight based on total weight of the composition. Polypropylene homopolymers are preferred (E.g. CAS #9003-07-0). Specific commercially available examples of component A include 5D49 polypropylene resin from The Dow Chemical Company, as well as 5E16S, CDX5E66, H533-35RGU, H700-12, and H7012-35RN, all available from The Dow Chemical Company. Examples of specific suitable copolymers include Dow Polypropylene C719-35, C700-35, C705-44NA, C758-80NA, C759-21NA, DS6D21, and NRD6-589, all available from The Dow Chemical Company. Polypropylenes such as these can also be used with glass fillers in the preferred embodiment where the photovoltaic cell assembly includes glass. The glass fillers are described in more detail below.

Component B which is a polyethylene homopolymer or an ethylene/α-olefin copolymer or combinations thereof which has a melt index of between 1 and 100 g/10 minutes and a density of at least 0.85 g/cm³ more preferably at least 0.86, and most preferably at least 0.865 and preferably less than 0.97, more preferably less than 0.92 and most preferably less than 0.89. The amount of component B is preferably at least 5%, more preferably at least 10%, and most preferably at least 20% and preferably less than 30% by weight based on total weight of the composition. Ethylene/α-olefin copolymers are preferred such as Engage™ polyolefins from The Dow Chemical Company (e.g. CAS#26221-73-8). Suitable materials for Component B include Dow ENGAGE™ 8200, 8207, 7447, 8130, 8137, 8411, 8400, 8407, 8401, and 8402 (all available from The Dow Chemical Company); Dow AFFINITY EG8200 (available from The Dow Chemical Company); and Exxon EXACT 8210, 5371, and 0210, available from Exxon Mobil Chemical Company.

The compositions useful in this invention can comprise an optional component C which is a fire resistant material, preferably an inorganic fire resistant material. This inorganic material may be for example metal carbonates (such as calcium carbonate), metal hydroxides, metal oxides, etc. Examples of suitable component C include aluminum trihydrate (ATH), magnesium hydroxide, zinc borate, antimony trioxide, zinc hydrostannate, silica, aluminosilicate clays, graphite, and ammonium polyphosphate. The inorganic fire resistant material is preferably an alkaline earth metal hydroxide, such as calcium hydroxide or magnesium hydroxide but is more preferably magnesium hydroxide. Aluminum hydroxide, or aluminum trihydrate (ATH) is also preferred. It is preferred that the amount of iron in this component is less than 100 parts per million based on total weight of the inorganic fire resistant material. The iron content can be determined by inductively coupled plasma mass spectrometry. In addition or as an alternative to the inorganic fire retardant, an organic fire retardant is optionally used. Examples of organic fire retardants are well-known in the art and include hexabromocyclododecane, decabromodiphenyloxide, tetrabromo-bisphenol-A, brominated polystyrene, tetrakis(hydroxymethyl)phosphonium salts, tri-o-cresyl phosphate, and tris(2,3-dibromopropyl)phosphate. The amount of component C is preferably at least 10%, more preferably at least 20%, most preferably at least 25% and preferably less than 50% more preferably less than 40% and most preferably less than 35% by weight based on total weight of the composition.

In the preferred embodiment of the first embodiment where the photovoltaic cell assembly includes a glass layer, the composition preferably comprises polypropylene and a reinforcement component in amounts up to 50% by weight. The polypropylenes may be those set forth for Component A or other commercially available polypropylenes. Examples of commercially available polypropylenes with a reinforcement component pre-blended into the polypropylene include RTP 101, RTP 102, RTP 103 and RTP 105 from RTP having 10, 15, 20 and 30% short glass fibers respectively and Polyone™ PP30LGF from Polyone having 30% long glass fiber.

Polyolefins (e.g. polypropylenes, polyethylenes and copolymers of propylene and ethylene) are useful in the present invention because that they can provide good adhesion to many of the materials that may be found at the edges or surfaces of the photovoltaic cell assembly. This enhances the structural integrity of the article.

Suitable reinforcement components can be used to reinforce the polymeric composition in order to improve certain physical properties such as strength, impact resistance, and stiffness as opposed to fillers which contribute only slightly to strength. Suitable reinforcements include fibrous reinforcements, which include glass fibers, carbonaceous fibers, polymeric fibers, inorganic fibers, metal fibers, and combinations thereof. Glass fibers may include rovings, chopped fibers, or milled fibers. Chopped glass fibers may range in length from 3 to 50 mm In general, milled fibers are less than 1.5 mm Examples may include glass fibers with an aspect ratio greater than 0.5, more pref greater than 0.7 and in some embodiments long glass fibers with aspect ratio greater than 10, but less than 100.

Carbonaceous fibers suitable as reinforcements include graphite fibers and carbon nanotubes, including single-wall carbon nanotubes. Polymeric reinforcements include Aramids such as Kevlar. Polyester or polyimide fibers may also be used. Inorganic fibers include whiskers of aluminum oxide, potassium titanate, beryllium oxide, magnesium oxide, silicon carbide, titanium boride, and inorganic continuous boron fibers. Metal fibers include steel, aluminum, and other metals drawn into continuous filaments. Such reinforcement components optionally can be used in the composition of embodiments three and four in amounts up to 15% by weight.

The body portion compositions may also optionally include various other components such as UV absorbers, UV stabilizers, colorants, antioxidants, heat stabilizers, flow modifiers, additional polymeric components, and the like. Specifically it is contemplated that the compositions may include:

a component D which is a UV absorber or UV absorbing pigment in amounts up to 10% by weight. The UV absorber may be any absorber of UV radiation known in the art such as, for example, inorganic UV stabilizers and pigments. Suitable inorganic UV stabilizers include carbon black, graphite, titanium dioxide, zinc oxide, clays, and, mixed metal oxides. Preferably, the UV absorber is present in amounts of at least 0.3%, more preferably at least 0.6%, and most preferably at least 0.8% by weight of the total composition. Carbon black may be used and is conveniently provided in a pre-compounded form with a compatible polymer such as polyethylene (preferred is linear low density polyethylene) in amounts such that the pigment comprises at least 30%, preferably at least 40% of the compounded material. The amount of the compounded material used is preferably at least 1%, more preferably at least 2% by weight of the total composition;

a component E which is a UV stabilizer in amounts up to 3% by weight of a UV stabilizer. Any known UV stabilizer may be used. For example hindered amines and benzophenones may be used but hindered amine light stabilizers are preferred. A commercially available material may be Cyasorb™ from Chemtura, BLS1770 from Mayzo. Other suitable organic UV stabilizers include hindered amine compounds such as AMPACET 10407 and 10478 (available from Ampacet Corp), Tinuvin 770, 765, 622FF and 353FF and CHIMISSORB 119 and 944FL (all available from CIBA), triazine compounds, such as Tinuvin 157FF (available from CIBA) and hydroxyphenyl benzotriazoles, such as Tinuvin 328 (available from CIBA);

a component F which is one or more antioxidants in amounts up to 2% by weight. Any known antioxidant for polymeric compositions may be used. Examples include phenolic antioxidants which optionally include a metal deactivator. These antioxidants may be used in combination with each other. The preferred total amount of antioxidants is up to 2% by weight, more preferably up to 1% by weight and preferably at least 0.1% by weight. The Irganox™ products from Ciba Geigy are useful commercial examples of such antioxidants;

a component G which is a sulfur containing long-term heat stabilizer or antioxidant in amounts up to 2% by weight. The heat stabilizer could be any such component known in the art. Examples include thioesters, thioethers and thiophenols. The heat stabilizer is preferably used in an amount of at least 0.2% by weight more preferably at least 0.5 weight percent. Examples of sulfur-containing secondary antioxidants include sulfides, disulfides, specifically: 2,2′-thiobis(4-methyl-6-tert-butylphenol) (IRGANOX 1081); tetrakis(3-laurylthiopropionyloxymethyl)methane; lauryl 3,3′-thiodipropionate (IRGANOX PS 800); stearyl 3,3′-thiodipropionate (SEENOX DS); Pentaerythritol tetrakis (β-laurylthiopropionate) (NAUGARD 412S); distearyl disulfide (HOSTANOX SE 10); dilauryl 3,3′-thiodipropionate (DLDTP) (ADVASTAB 800); dimyristyl 3,3′-thiodipropionate; propionic acid, 3,3′-thiobis-, didodecyl ester, ditridecyl 3,3′-thiodipropionate (CYANOX 711); distearyl-3,3′-thiodipropionate (DSTDP), or dioctadecyl 3,3-thiodipropionate (ADVASTAB 802); and dimyristyl 3,3′-thiodipropionate (SEENOX DM), to name a few;

a component H which is an additional propylene ethylene copolymer in amounts of up to 20% by weight. Preferably these copolymers would have weight average molecular weights of at least 20,000. Examples of such copolymers include Versify polymers from The Dow Chemical Company. This component may be used in addition to or as an alternate to component B if higher temperature ratings are needed;

a component I which is a filler. Examples include talc, colorant pigments in amounts up to 15% by weight. Antistatic agents, nucleating agents, and other additives may also be used as appropriate.

In addition or as an alternative to the inorganic fire retardant, an organic fire retardant is optionally used. Examples of organic fire retardants are well-known in the art and include hexabromocyclododecane, decabromodiphenyloxide, tetrabromo-bisphenol-A, brominated polystyrene, tetrakis(hydroxymethyl)phosphonium salts, tri-o-cresyl phosphate, and tris(2,3-dibromopropyl)phosphate.

The weight percents herein are based on total weight of the composition unless otherwise specified.

### Example 1

Compositions are prepared using the ingredients identified in Table 1. The amounts of the ingredients in weight % based on total weight of the composition are as listed in table 2.

TABLE 1

| | |
|---|---|
| Component A | 5D49 polypropylene resin from The Dow |
| | Chemical Company (xylene solubles 2.7-3.9%) |
| Component A′ | H7012-35 RN polypropylene from The Dow |
| | Chemical Company (xylene solubles 6-8%) |
| Component B | Engage 8200 from The Dow Chemical |
| | Company an ethylene/octene copolymer |
| | with a 5 g/10 min melt flow rate CAS# 26221- |
| | 73-8 |
| Component C | FR-20-100 Magnesium hydroxide from ICL |
| | CAS# 1309-42-8 |
| Component D | DFNA 0037 (a linear low density |
| | polyethylene with a carbon black content of |
| | 43 wt % to 47 wt %) from The Dow Chemical |
| | Company |
| Component E | Cyasorb 3853 from Chemtura |
| Component F | Irganox 1010 and Irganox 1024MD in 4:1 |
| | weight ratio (both from Ciba Geigy) |
| Component G | Naugard 412S from Chemtura. |
| Component H | Versify ™ 4200 (from The Dow Chemical |
| | Company) polyolefin plastomer ethylene |
| | copolymer with a molecular weight number |
| | average of 35,000 and a CAS# 9010-79-1 |

TABLE 2

| Sample | | | | | | | | | |
|---|---|---|---|---|---|---|---|---|---|
| number | A | A′ | B | C | D | E | F | G | H |
| 1 | 25.98 | — | 12.8 | 30 | 5 | 0 | .32 | .2 | 25.7 |
| 2 | 31.18 | — | 12.8 | 30 | 5 | 0 | .32 | .2 | 20.5 |
| 3 | 22.68 | — | 19.3 | 30 | 5 | 0 | .32 | .2 | 22.5 |
| 4 | 27.18 | — | 19.3 | 30 | 5 | 0 | .32 | .2 | 18 |
| 5 | 20.88 | — | 12.8 | 30 | 5 | 0 | .32 | .2 | 30.8 |
| 6 | 18.18 | — | 19.3 | 30 | 5 | 0 | .32 | .2 | 27 |
| 7 | 45.68 | — | 18.8 | 30 | 5 | 0 | .32 | .2 | 0 |
| 8 | — | 38.78 | 25.7 | 30 | 5 | 0 | .32 | .2 | 0 |
| 9 | 48.48 | — | 16 | 30 | 5 | 0 | .32 | .2 | 0 |
| 10 | 38.78 | — | 25.7 | 30 | 5 | 0 | .32 | .2 | 0 |
| 11 | 27.18 | — | 19.3 | 30 | 5 | 0 | .32 | .2 | 18 |
| 12 | 44.18 | — | 20 | 30 | 5 | .3 | .32 | .2 | 0 |
| 13 | 44.2 | — | 20 | 30 | 5 | 0 | .3 | .5 | 0 |
| 14 | 41.6 | — | 22 | 30 | 5 | 0 | .5 | .9 | 0 |

Components A (or A′ as the case may be), B, D, and H can be blended in pellet form and fed into the feed throat of a twin screw extruder. Components E, F, G, and I can be blended together and fed into the feed zone of the twin screw extruder. Component C can be fed into the metering zone of the twin screw extruder. The following two commercially available compositions were also used: specifically MAXXIM™ 7c31 from Polyone and Dow 7C54H were used in samples C1 and C2, respectively. The twin screw extruder barrel temperature is kept below 230° C. Samples were then prepared for different test methods using ASTM D3641-97 (injection molding of test specimens of thermoplastic material) and conditioned prior to testing via ASTM D618-08. Samples made substantially according to the preceding are tested for melt flow rate (MFR), DSC Endotherm, Shrinkage, IZOD impact at 23° C., flexurual modulus and tensile elongation as set forth by the methods articulated above for each method. Results are shown in Table 3.

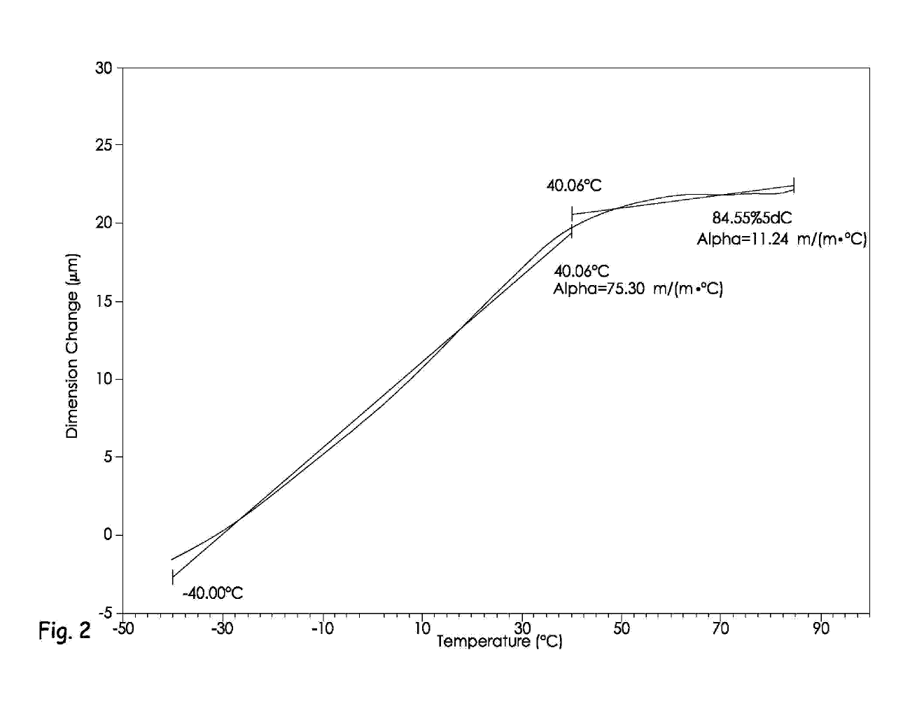

A photovoltaic article similar in structure to the example in FIG. 1 is injection molded using Formulations 10 and 14 around a laminated photovoltaic cell assembly structure. As shown in FIG. 2, the CLTE of Formulation 14 is 75.3 microns/m-° C. between −40° C. and 40° C. and is 11 microns/m-° C. between 40 and 85° C. For purposes of this invention the larger CLTE is used for determining CLTE relative to the CLTE of the photovoltaic cell assembly.

TABLE 3

| Sample ID | 1 | 2 | 3 | 4 | 5 | 6 | 7 | 8 | 9 | 10 | 11 | 12 | 13 | 14 | C1 | C2 |
|---|---|---|---|---|---|---|---|---|---|---|---|---|---|---|---|---|
| MFR (g/10 | 12.4 | 10.4 | 11.2 | 11 | 12.8 | 16.8 | 13.7 | 12.3 | 8 | 10 | 15 | 15.2 | 13.8 | 14 | 14.7 | 11 |
| min) | | | | | | | | | | | | | | | | |
| DSC | 165.3 | 166.2 | 166.3 | 164.3 | 166 | 162.9 | 149.9 | 150.6 | 167.8 | 167.3 | 164.3 | 165.5 | 164.5 | 165.63 | 169.3 | 170.4 |
| EndoTherm | | | | | | | | | | | | | | | | |
| (° C.) | | | | | | | | | | | | | | | | |
| Shrink data (%) | 0.9 | 0.85 | 0.75 | 0.75 | 0.65 | 0.6 | 1.2 | 0.9 | 1.3 | 1.1 | 0.85 | 1.1 | 0.9 | 0.9 | 1.2 | 1.5 |
| IZOD at 23 C.* | PB | PB | NB | NB | NB | NB | FB | NB | FB | NB | NB | PB | NB | NB | FB | FB |
| Flexural | 537 | 675 | 379 | 482 | 434 | 351 | 951 | 503 | 1392 | 744 | 406 | 923 | 896 | 800 | 1027 | 834 |
| Modulus (MPa) | | | | | | | | | | | | | | | | |
| Tensile | 584 | 433 | 585 | 571 | 531 | 556 | 20 | 563 | 67 | 499 | 570 | 48 | 92 | 400 | 625 | 534 |
| Elongation (%) | | | | | | | | | | | | | | | | |

*PB = partial break, NB = no break, FB = full break

### Comparative Example 2

A photovoltaic article similar in structure to the example in FIG. 1 is injection molded using various overmold compositions around a laminated photovoltaic cell assembly structure. In one sample the overmold composition is an unfilled Infuse™ 9817 olefin block copolymer from The Dow Chemical Company. The resulting molded article using the unfilled olefin block copolymer shows significant deformation after molding. Filled versions polymer mold well but do not have sufficient heat stability to achieve the desired RTI.

In a third sample, a polypropylene filled only with talc is used. This also showed unacceptable shrinkage and deformation after molding.

### Example 3

Sample formulations are made using all of the overmold components in Example 1, Sample 14 except the amount of Component C (FR-20-100 Magnesium hydroxide from ICL CAS#1309-42-8) which is progressively reduced from 30% to 0% at 5% increments (ie. 30, 25, 20, 15, 10, 5, 0%). The resulting samples are tested as in Example 1 and are injection molded around a photovoltaic cell assembly.

### Example 4

Two sample formulations similar to Sample 14 are made. The two samples differ only in the identity of Component C. In one sample, component C is a Magnesium hydroxide material with a Fe content in excess of 100 ppm (MAGSHIELD S provided by Martin Marietta) and in the other sample component C is a Magnesium hydroxide material with an Fe content of <100 ppm (FR-20-100 s10 from ICL CAS#1309-42-8) is used. An article made by injection molding the formulation where the Magnesium hydroxide containing >100 ppm is subjected to elevated temperature testing, 150° C. for approximately 350 hours, and the molded material exhibits a surface crazing (cracking), therefore making the appearance unacceptable from an aesthetic point of view as well as compromising the long term outdoor viability of the photovoltaic article. In contrast, an article injection molded using the formulation containing a Magnesium hydroxide material (component C) with an Fe content of <100 ppm, and said article is then subjected to elevated temperature testing, 150° C. for approximately 750 hours, the exhibits no surface crazing (cracking), making the appearance acceptable from an aesthetic point of view as well as demonstrating the long term outdoor viability of the photovoltaic article.

### Example 5

A photovoltaic article similar in structure to the example in FIG. 1 is injection molded using an overmold composition around a laminated photovoltaic cell assembly structure. The overmold material contains at least polypropylene, long glass fibers (approx. 30% by weight), flame retardant, and a UV stabilizer (RTP Imagineering Plastics, product RTP 105 CC FR UV).

### Example 6

A laminate structure containing a glass top sheet having a CLTE of ˜9 microns/meter-° C. is injection molded to create a photovoltaic article similar in structure to the example in FIG. 1 using the overmolding composition described as DLGF9411. DLGF9411 is a long glass fiber polypropylene based material that consists of at least 55% INSPIRE™ H7012-35RN polypropylene homopolymer (from The Dow Chemical Company), 40% long glass fiber, maleic anhydride grafted polypropylene coupling agent, along with UV stabilizers and antioxidants combined using a specialized pultrusion process to create a nominal 12 mm long pellet. The composition has the following properties.

TABLE 3

| Physical Property | Condition | Method | Results |
|---|---|---|---|
| Izod impact (J/m/kJ/m²) | Notched, 23° C. | ASTM | 222 |
| | | D256 | |
| Tensile strength at break | 5 mm/min | ASTM | 115 |
| (MPa) | | D638 | |
| Flexural modulus (MPa) | 1.3 mm/min | ASTM | 7950 |
| | | D790 | |
| Heat aging Property | 500 h @ 150° C./1000 H | | |
| (estimate of | @ 140 c | | |
| RTI—relative | | | |
| thermal index) Retention | | | |
| (%) Tensile Strength | | | 108% |
| Notched Izod, 23 C. | | | 99.80% |
| Elongation at Break (%) | 5 mm/mmin | ASTM | 2.3 |
| | | D638 | |
| Mold Shrinkage (%), | Parallel to | | 0.12/0.79 |
| after 24 hr | flow/Perpendicular to | | |
| | flow during injection | | |
| | molding | | |
| Coefficient of Linear | Parallel to | | 14.7/42.5 |
| Thermal Expansion | flow/Perpendicular to | | |
| (microns/m-° C.) | flow during injection | | |
| | molding | | |

### Example 7

A sample formulation is made in a manner similar to the overmold components in Example 1, Sample 14 except the amount by weight of Component A is 53% (Dow polypropylene 5D49), Component B is 18.6% (Dow ENGAGE 8200), Component C is 0.5% graphite flake (A60 Synthetic Graphite flake, available from Asbury Graphite Mills, Inc.), Component D is 5% (DFNA 0037), Component E is 0.2% Chemissorb 119 (0%), 0.3% Tinuvin 770, and 0.15% Tinuvin 328, Component F is 0.9% (Irganox 1010/Irganox 1024 MD 4:1 ratio), Component G is 0.3% Nauguard 412S, Component H is 9% (VERSIFY 3200, available from Dow Chemical). In addition, 0.5% of a brominated FR additive (polybrominated diphenyloxide), 10% of long glass fibers, and 2% maleic acid-grafted polypropylene (Polybond 3200, available from Chemtura Corporation) is used. After blending all of the components, the composition is useful for injection molding to produce BIPV articles desirably having an RTI Electrical and an RTI Mechanical Strength rating, each of which is at least 85° C., good moldability, low shrinkage, good weatherability, excellent surface appearance, excellent UV resistance, and is relatively tough and strong, with sufficient low-temperature impact performance to resist hail impact damage under use.

What is claimed is:

1. A photovoltaic article comprising a photovoltaic cell assembly and a body portion connected to at least one edge of the photovoltaic cell assembly wherein the body portion comprises a composition having the following characteristics:
a) a melt flow rate of at least 5 g/10 minutes and no greater than 100 g/10 minutes;
b) a coefficient of linear thermal expansion (CLTE) which is within factor of 20 of the CLTE of the photovoltaic cell assembly; and
c) an RTI Electrical and an RTI Mechanical Strength rating, each of which is at least 85° C.

2. The photovoltaic article of claim 1 wherein the body portion comprises a polypropylene containing up to 50% by weight of a reinforcement component.

3. A photovoltaic article comprising a photovoltaic cell assembly and a body portion connected to at lest one edge of the photovoltaic cell assembly wherein the body portion comprises a composition having the following characteristics:
a) a melt flow rate of at least 5 g/10 minutes and no greater than 100 g/10 minutes;
b) a flexural modulus of at least 500 MPa and no greater than 1500 MPa
c) a tensile elongation at break of at least 100% of original length; and
d) an RTI Electrical and an RTI Mechanical Strength rating, each of which is at least 85° C.

4. The photovoltaic article of claim 3 wherein the composition of the body portion has a coefficient of linear thermal expansion (CLTE) which is within factor of 20 of the CLTE of the photovoltaic cell assembly.

5. The article of any of the claim 1 further characterized in that a roofing construction containing the article passes the UL 790 flammability test class B.

6. The article of claim 3 wherein the article passes class B of the UL 790 flammability test.

7. The article of claim 1 wherein the composition is characterized by an after mold shrinkage of less than 2%.

8. The article of claim 3 wherein the composition is characterized by an after mold shrinkage of less than 2%.

9. A photovoltaic article comprising a photovoltaic cell assembly and a body portion connected to at least one edge of the photovoltaic cell assembly wherein the body portion comprises (a) from 20 to 80% by weight of a polypropylene, a copolymer of propylene and ethylene, or a mixture thereof which has a melt flow rate of between 5 and 100 g/10 minutes;
(b) from 5 to 30% by weight of a polyethylene, an ethylene/α-olefin copolymer, or a mixture thereof which has a melt flow index melt index of between 1 and 100 g/10 minutes and a density of at least 0.85 g/cm³ and less than 0.97; and
(c) from 10 to 50% by weight of an inorganic fire resistant material.

10. The article of claim 1 wherein the body portion comprises (a) from 20 to 80% by weight of a polypropylene, a copolymer of propylene and ethylene, or a mixture thereof which has a melt flow rate of between 5 and 100 g/10 minutes;
(b) from 5 to 30% by weight of a polyethylene, an ethylene/α-olefin copolymer, or a mixture thereof which has a melt flow index melt index of between 1 and 100 g/10 minutes and a density of at least 0.85 g/cm³ and less than 0.97; and
(c) from 10 to 50% by weight of an inorganic fire resistant material.

11. The article of claim 3 wherein the body portion comprises (a) from 20 to 80% by weight of a polypropylene, a copolymer of propylene and ethylene, or a mixture thereof which has a melt flow rate of between 5 and 100 g/10 minutes;
(b) from 5 to 30% by weight of a polyethylene, an ethylene/α-olefin copolymer, or a mixture thereof which has a melt flow index melt index of between 1 and 100 g/10 minutes and a density of at least 0.85 g/cm³ and less than 0.97; and
(c) from 10 to 50% by weight of an inorganic fire resistant material.

12. The article of claim 8 wherein the amount of component (a) is from 30 to 80% by weight and the amount of component (b) is from 20 to 30% by weight.

13. The article of claim 8 wherein component (c) contains less than 100 parts per million iron.

14. The article of claim 8 further wherein the body portion further comprises one or more of the following components:
(d) a UV absorber or UV absorbing pigment in amounts up to 10% by weight;
(e) a UV stabilizer in amounts up to 3% by weight;
(f) one or more antioxidants in combined amounts up to 2% by weight;
(g) a heat stabilizer in amounts up to 2% by weight;
(h) an additional propylene ethylene copolymer in amounts of up to 20% by weight; and a
(i) additional inorganic filler or reinforcement component in amounts up to 15% by weight.

15. A composition comprising (a) from 30 to 80% by weight of a polypropylene or a copolymer of propylene and ethylene which has a melt flow rate of between 5 and 100 g/10 minutes;
(b) from 5 to 30% by weight of a polyethylene, an ethylene/α-olefin copolymer, or a mixture thereof which has a melt flow index melt index of between 1 and 100 g/10 minutes and a density of at least 0.85 g/cm³ and less than 0.97; and
(c) from 10 to 50% by weight of an inorganic fire resistant material.

16. The composition of claim 15 containing less than 100 ppm iron.

17. The composition of claim 15 further comprising one or more of the following components:
(d) a UV absorber or UV absorbing pigment in amounts up to 10% by weight;
(e) a UV stabilizer in amounts up to 3% by weight;
(f) one or more antioxidants in combined amounts up to 2% by weight;
(g) a heat stabilizer in amounts up to 2% by weight;
(h) an additional propylene ethylene copolymer in amounts of up to 20% by weight; and a
(i) additional inorganic filler in amounts up to 15% by weight.
